(19) United States
(12) Patent Application Publication
(10) Pub. No.: US 2009/0170259 A1
(43) Pub. Date: Jul. 2, 2009

(54) ANGLED IMPLANTS WITH DIFFERENT CHARACTERISTICS ON DIFFERENT AXES

(75) Inventors: Brian Edward Hornung, Richardson, TX (US); Rajesh Gupta, Dallas, TX (US); Mike Voisard, Mesquite, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/340,140

(22) Filed: Dec. 19, 2008

Related U.S. Application Data
(60) Provisional application No. 61/017,264, filed on Dec. 28, 2007.

(51) Int. Cl. H01L 21/8238; H01L 21/265; H01L 21/336

(52) U.S. Cl. 438/231; 438/525; 438/302; 257/E21.334; 257/E21.433; 257/E21.634

(57) ABSTRACT

One embodiment relates to a method of forming an integrated circuit. In this method, at least one dopant species of a first conductivity type is implanted in a first manner along a first axis to form first pocket implant regions extending at least partially under some gates. At least one dopant species of the first conductivity type is then implanted in a second manner that differs from the first manner along a second axis that is laterally rotated with respect to the first axis to form second pocket implant regions extending at least partially under other gates.

### RELATED APPLICATIONS

This application claims the priority of U.S. Provisional Application Ser. No. 61/017,264, filed Dec. 28, 2007, entitled “Angled Implants with Different Characteristics on Different Axes”.

### FIELD OF INVENTION

The present invention relates generally to semiconductor processing, and more particularly to a method of performing angled implantations.

### BACKGROUND OF THE INVENTION

Implantation of dopants into a semiconductor substrate (or epitaxial silicon layer which overlies the semiconductor substrate) is important in semiconductor device fabrication. Many different implantation steps need to be performed, for example, to form pockets regions, form drain extensions, form source and drain regions, dope the polycrystalline silicon (“poly” or “polysilicon”) gate structure, form isolation structures, and to increase or decrease the conductivity of semiconductor structures. A problem with all of these implantation steps is that they may require separate masks so as to block the implantation of dopants from one region while exposing other regions to the implantation of dopants. Formation of these masks is very expensive and can be quite difficult to implement due to ever shrinking feature sizes and the difficulties associated with present limitations on photolithography. Some relief from these problems can be achieved by using existing structures to define the regions in which dopants are implanted. However, this so-called self alignment methodology cannot solve all the problems related to precisely implanting dopants into these semiconductor structures.

As technology nodes advance, it is advantageous for designers have access to several different types of transistors, each of which may have different electrical characteristics. The traditional approach for providing designers with several types of transistors has been to have a unique set of lithographic steps that corresponds to each type of transistor. While this solution is generally effective, it suffers from high financial costs due to the significant number of masks involved. Therefore, there is a need for a methodology that will result in an efficient manner to alter the device characteristics of various transistors on an integrated circuit without having to use an additional mask.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its primary purpose is merely to present one or more concepts of the invention in a simplified form as a prelude to the more detailed description that is presented later.

One embodiment relates to a method of forming an integrated circuit. In this method, at least one dopant species of a first conductivity type is implanted in a first manner along a first axis to form first pocket implant regions extending at least partially under some gates. At least one dopant species of the first conductivity type is then implanted in a second manner that differs from the first manner along a second axis that is laterally rotated with respect to the first axis to form second pocket implant regions extending at least partially under other gates.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIGS. 1A-1C show a top view and cross sectional views of implanting angled implants into a semiconductor wafer;

FIG. 2 shows a flowchart that shows one embodiment of a method for manufacturing an integrated circuit;

FIGS. 3-9 show cross-sectional views of an integrated circuit at various stages of manufacture; and

FIG. 10 shows a top view of another embodiment for implanting angled implants into a semiconductor wafer.

### DETAILED DESCRIPTION OF THE INVENTION

One or more aspects of the present invention are described with reference to the drawings, wherein like reference numerals generally refer to like elements throughout, and wherein the various structures are not necessarily drawn to scale. In the following description, for purposes of explanation, numerous specific details are set forth in order to provide a thorough understanding of one or more aspects of the present invention. It may be evident, however, to one skilled in the art that one or more aspects of the present invention may be practiced with a lesser degree of these specific details.

Aspects of this disclosure relate to orienting devices' gates at different angles relative to one another so that angled implants, such as pocket implants, can be tailored to affect those devices differently. For example, by differing the angled implants as a function of independent axes that are laterally aligned with the gates, drive currents of speed path transistors associated with a high-speed microprocessor core could be altered relative to drive currents of SRAM memory array transistors. Although several embodiments are described herein where the devices are metal oxide semiconductor field effect transistors (MOSFETs), these embodiments could be altered by one of ordinary skill in the art to utilize the invention with different types of devices and integrated circuits.

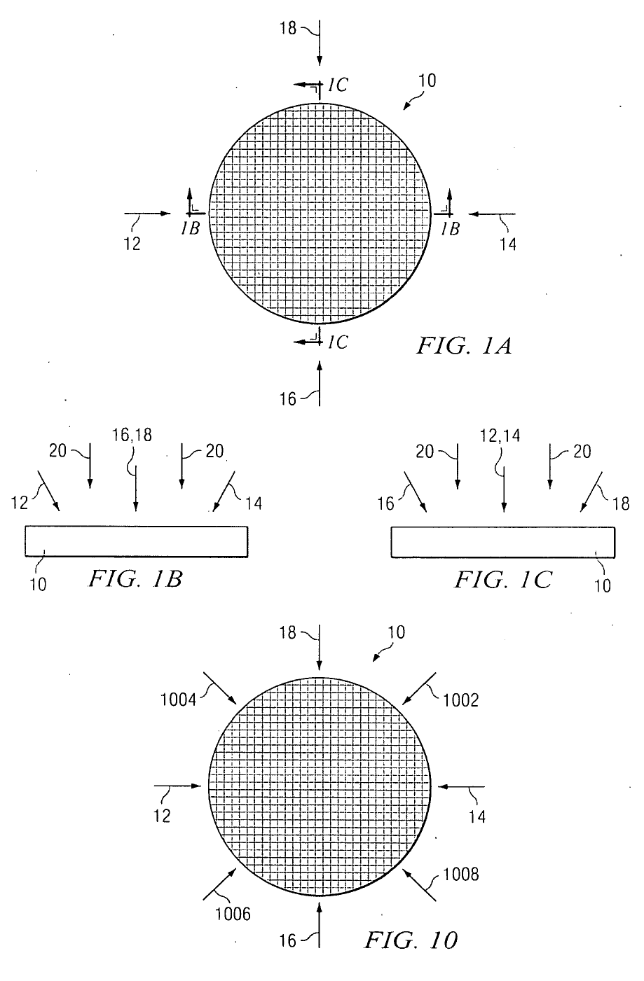

To provide a broad context, FIGS. 1A-1C show one manner of performing an angled implant, such as a “pocket implant” (which could also be referred to as a “halo implant” in some technologies). In these figures, one can see a semiconductor wafer 10 into which a dopant species is implanted at an angle relative the wafer's surface. As shown, four angled implants 12, 14, 16, 18 are utilized at each of four quadrants around a wafer (e.g., at 0°, 90°, 180°, 270°, or at 45°, 135°, 225°, 315°). More specifically, angled implants 12 and 14, for example, are rotated about 180° from each other (laterally opposed) and may be tilted at a common angle relative to the surface of the wafer 10 (see FIG. 1B). Similarly, angled implants 16 and 18 are rotated about 180° from each other, and may also be tilted at the common angle relative to the surface of the wafer 10 (see FIG. 1C). Although the wafer or a platter containing multiple wafers is typically rotated while the implanter beam is held fixed, the implanter could potentially be rotated about the wafer if desired.

In some aspects of the present invention, the pocket implants may be provided with different characteristics on the various axes 12, 14, 16, 18. In some embodiments, one set of laterally opposing pocket implants could have one characteristic, while another set of laterally opposing pocket implants could have another characteristic. For example, pocket implants 12 and 14 may differ from pocket implants 16 and 18 with respect to dosage, energy, and/or implanted specie. In other embodiments, pocket implants along each axis can independently vary from the other axes. For example, pocket implant 12 may differ from each of pocket implants 14, 16, 18 with respect to dosage, energy, and/or implanted specie. Other combinations are also contemplated as falling within the scope of the present invention.

For purposes of contrast, FIGS. 1B-1C also show “normal” implants 20, wherein the normal implants 20 impact the wafer 10 at an angle normal or perpendicular to the surface of the wafer 10. For example, normal implants 20 may be used to form source/drain extension regions (e.g., LDD, MDD, or HDD regions) that are self-aligned with respect to a gate. Normal implants 20 may also be used to form source/drain regions that are self-aligned with respect to the gate and/or spacers.

As will be appreciated further below, angled implants such as pocket implants often penetrate under gates of transistors, thereby allowing a designer to alter the channel characteristics of those transistors. In some embodiments, the pocket implants may be used to control the voltage threshold (Vₜ) and improve the performance of a transistor by providing a means to scale the channel length and increase the transistor drive current without causing an increase in the off-state leakage current.

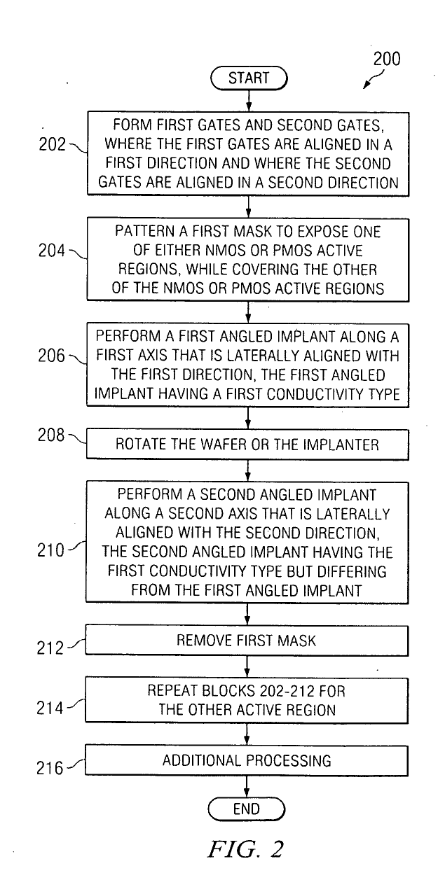

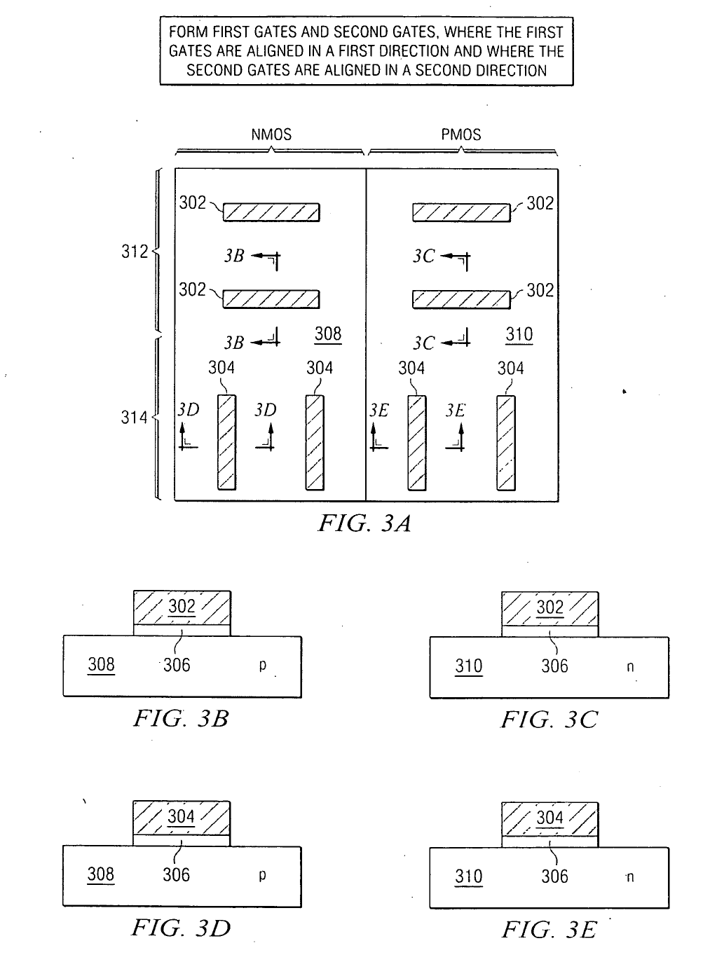

To further appreciate aspects of the invention, FIGS. 2-9 show some examples of methods for manufacturing an integrated circuit. More particularly, FIG. 2 shows a somewhat general method in flowchart form, and FIGS. 3-9 show a more detailed method as a series of cross-sectional views. Although these methods are illustrated and described below as a series of acts or events, it will be appreciated that the present invention is not limited by the illustrated ordering of such acts or events. For example, some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the devices and systems illustrated and described herein as well as in association with other structures not illustrated.

Referring now to FIG. 2, one can see the somewhat general method 200 where gates on the integrated circuit are aligned in at least two different directions. In this method 200, after a first mask is formed to expose one type of active region (e.g., nmos active region with p-type doping), first and second angled implants of a first conductivity (e.g., p-type) are implanted through holes in the first mask. These first and second angled implants are laterally rotated with respect to one another and may have different characteristics on their respective axes. The first mask is then removed, and a second mask is formed over the other type of active region (e.g., pmos active region with n-type doping). Third and fourth angled implants of a second conductivity (e.g., n-type) are then implanted through holes in the second mask. The third and fourth angled implants are also laterally rotated with respect to one another and may have different characteristics on their respective axes.

Due to the rotational relationship between the gates' alignments and the various angled implants axes, the channel characteristics of the differently aligned transistors can be tailored as a function of their alignment. For example, in one embodiment, gates of speed path transistors associated with a high-speed microprocessor core could be aligned in a first direction, but gates of SRAM transistors associated with an integrated SRAM array could be aligned in a second direction that is perpendicular to the first direction. Therefore, drive currents of the speed path transistors could be adjusted independently of the drive currents of the SRAM transistors by suitably adjusting the angled implants. This could allow designers to increase the speed at which the microprocessor core could perform, while also enhancing the yield of SRAM cells.

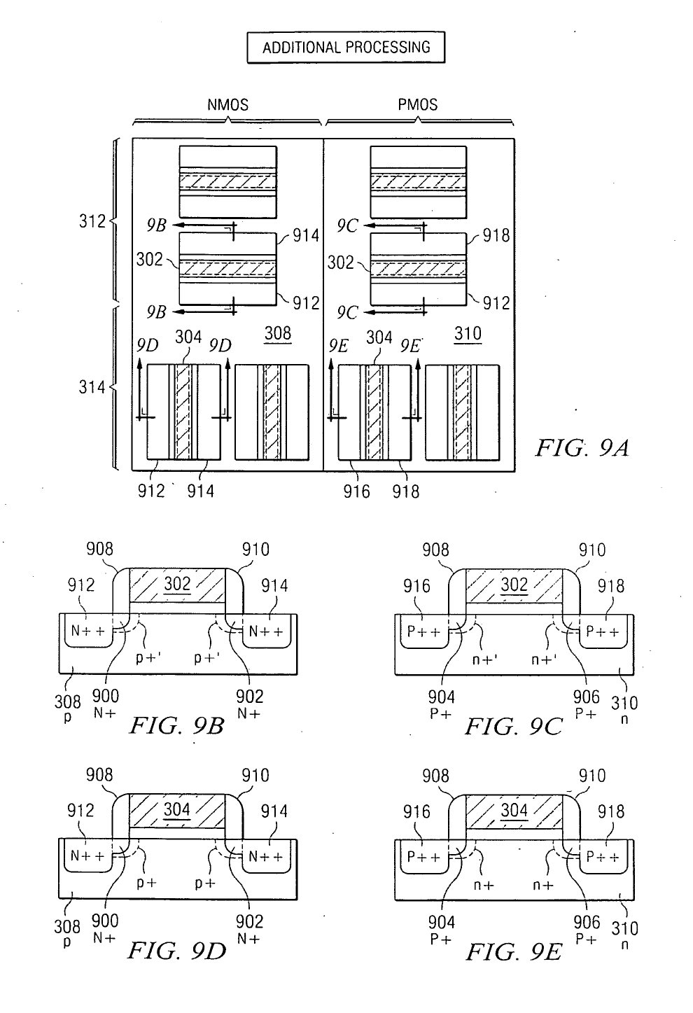

Referring now to FIGS. 3-9, one can see another more detailed embodiment illustrating an integrated circuit at various stages of manufacture. These figures show one example of some structures that could correspond to the blocks of method 200. More particularly, these figures show top-layout views (FIGS. 3A, 4A, 5A, etc.), and cross sectional views (FIGS. 3B-3E, 4B-4E, 5B-5E, etc.) as indicated. For purposes of clarity, the figures show junctions between p-type and n-type material as solid lines. For example, in FIG. 9B's illustrated NMOS device there is a p-n junction between source 912 and active region 308. By comparison, when the same type of doping is used but at different concentrations to establish different regions, dashed lines are used. For example, in FIG. 9B's NMOS device, source 912 has the same doping type as source extension region 900, albeit at different doping concentrations. Some layers may not be shown in all of the figures for purposes of clarity and readability.

FIG. 3 shows first gates 302 and second gates 304 formed over a thin dielectric 306 that overlies nmos active regions 308 and pmos active regions 310. According to the convention used herein, the nmos active regions 308 are p-type regions where nmos devices are formed. For example, the nmos active regions 308 could include p-wells implanted into the semiconductor body or grown epitaxially. Conversely, the pmos active regions 310 are n-type regions where pmos devices are formed. The pmos active regions 310 could include n-wells implanted into the semiconductor body or grown epitaxially, for example. In other illustrated embodiments, the semiconductor body could include other features, such as shallow trench isolation structures, extension wells, etc.

The first gates 302 are aligned in a first direction and the second gates 304 are aligned in a second direction. Often, the first direction will be perpendicular to the second direction, but need not be. Often, the first and second gates will be associated with one or more dies on the wafer. In one embodiment, the first gates 302 could be associated with one portion 312 of the integrated circuit, such as a speed path of a microprocessor, and the second gates 304 could be associated with another portion 314 of the integrated circuit, such as an SRAM memory array. By aligning the gates as shown, a dense layout may be achieved and the device characteristics of the devices associated with the first and second gates by be independently altered.

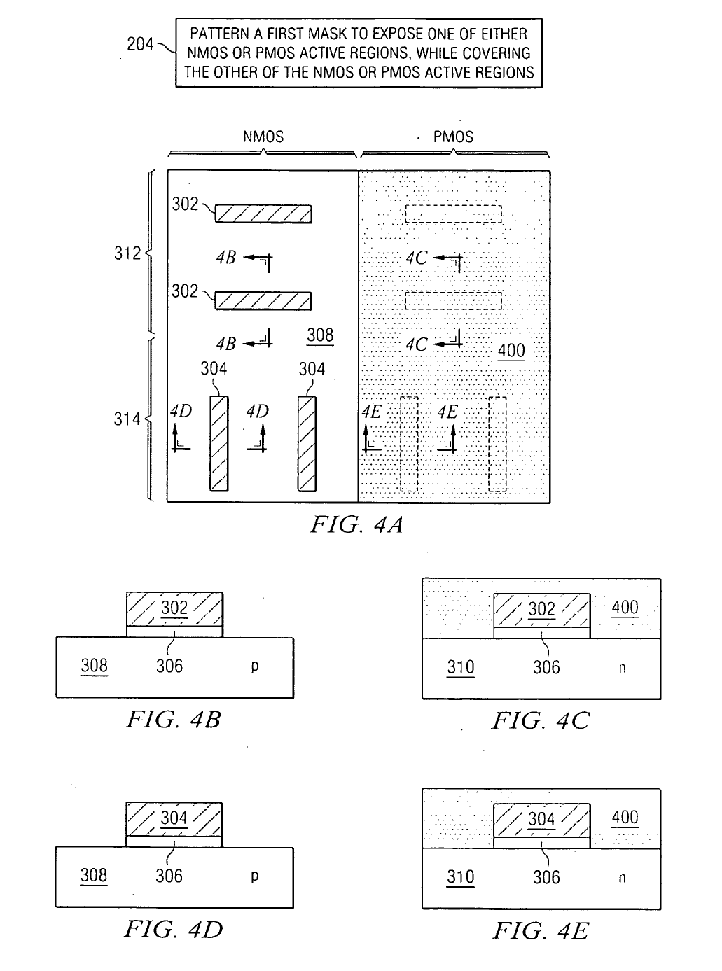

FIG. 4 shows a first mask 400 that has been formed so as to expose the NMOS active regions and cover the PMOS active regions. Typically, the first mask 400 comprises photoresist, although other masks, such as a hard mask, could also be used.

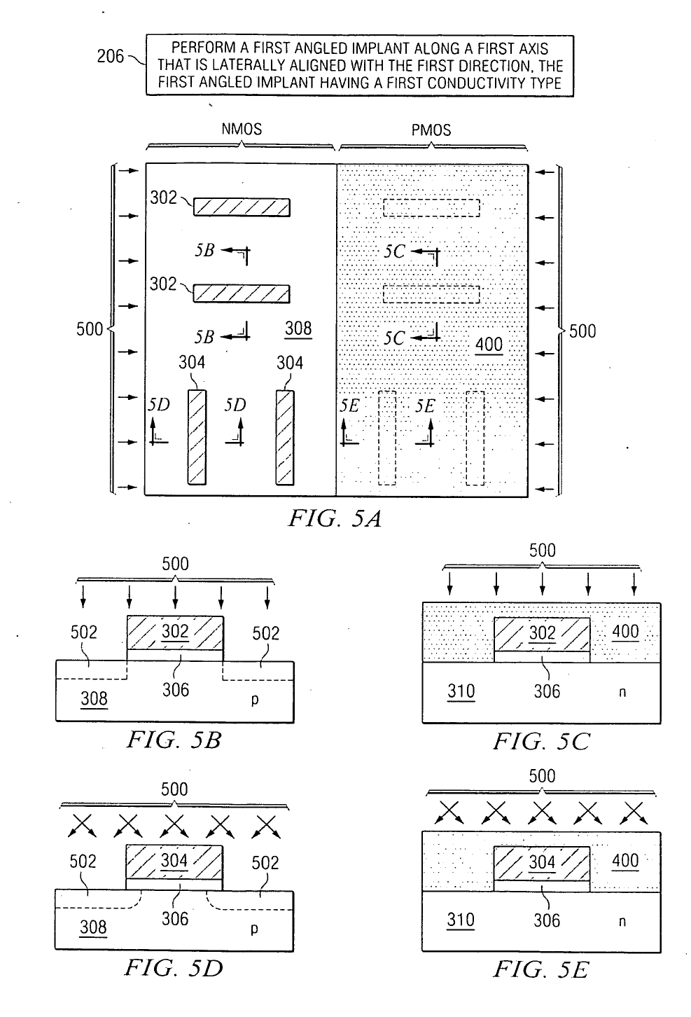

In FIG. 5, a first angled implant 500 (e.g., a p-type pocket implant) is performed along a first axis that is laterally aligned with the first direction. As FIG. 5D shows, this implant forms first implanted regions 502 respectively extending at least partially under the second gates 304. As FIG. 5B shows, the first angled implant may also form first implanted regions 502 that are self-aligned with respect to the first gates 302. Thus, the first angled implant 500 will generally not penetrate under the first gates 302 in a substantial way.

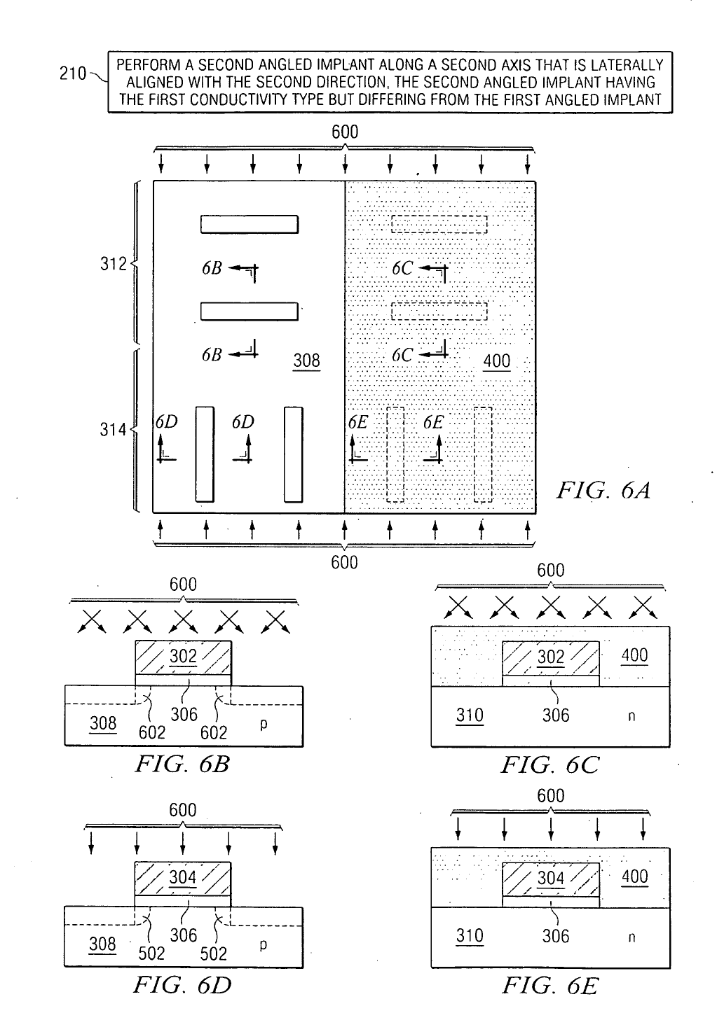

In FIG. 6, a second angled implant 600 (e.g., a p-type pocket implant) is performed along a second axis that is laterally aligned with the second direction. As FIG. 6B shows, this implant forms second implanted regions 602 respectively extending at least partially under the first gates 302. As FIG. 6D shows, the second angled implant will generally not penetrate under the second gates 304 in a substantial way. Thus, the regions not under the nmos active regions that are not under the gate, may often be similarly doped to one another.

Notably, by performing the second angled implant 600 in a manner that differs from the first angled implant 500, one can achieve different channel configurations. As shown in FIGS. 6B, 6D, the different manner in which the first and second angled implants are performed could result in the first implanted regions 502 having a first doping profile (e.g., p+), and the second implanted regions 602 having a second doping profile (e.g., p+′). Therefore, it will be appreciated that by independently varying the manner in which the angled implants are performed along independent axes, different channel configurations can be achieved.

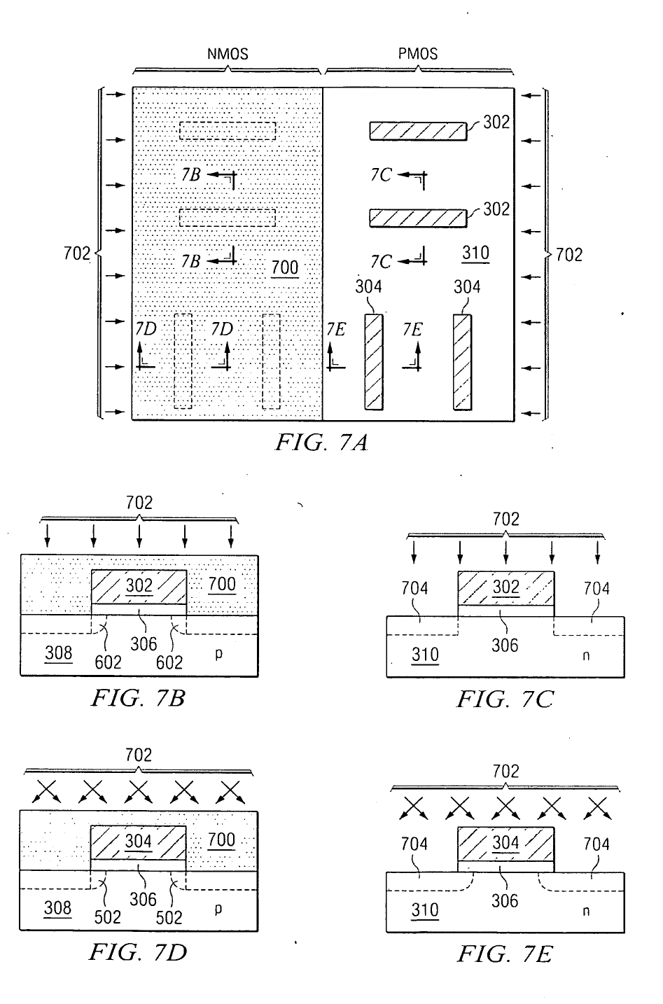

Referring now to FIG. 7, one can see that the first mask 400 has been removed and that a second mask 700 has been formed. While the second mask 700 is present, a third angled implant 702 (e.g., an n-type pocket implant) is performed along the first axis. As FIG. 7E shows, this implant forms third implanted regions 704 respectively extending at least partially under the second gates 304. As FIG. 7C shows, the third angled implant 702 may also form third implanted regions 704 that are self-aligned with respect to the first gates 302. Thus, the third angled implant will generally not penetrate under the first gates 302 in a substantial way.

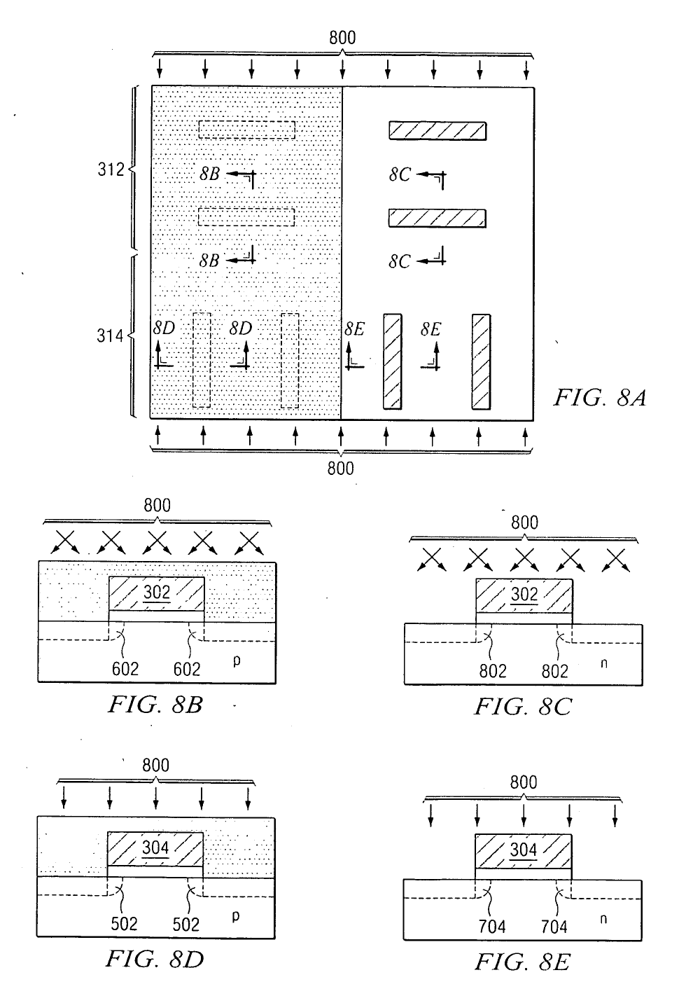

In FIG. 8, a fourth angled implant 800 (e.g., an n-type pocket implant) is performed along the second axis. As FIG. 8C shows, this implant forms fourth implanted regions 802 respectively extending at least partially under the first gates 302. As FIG. 8E shows, the fourth angled implant 800 will generally not penetrate under the second gates 304 in a substantial way.

Again, by performing the third angled implant in a manner that differs from the fourth angled implant, the third implanted regions 704 could have a third doping profile (e.g., n+) and the fourth implanted regions 802 could have a fourth doping profile (e.g., n+′), where the third and fourth doping profiles give rise to different channel characteristics.

As shown in FIG. 9, additional processing could be performed to form a functional integrated circuit. For example, in one embodiment, normal LDD implants could be used to form source/drain extension regions. For example, n-type source/drain extension regions (e.g., N+) 900, 902 that are self-aligned to the nmos gates could be implanted while the first mask 400 is present. Similarly, p-type source/drain extension regions (e.g., P+) 904, 906 that are self-aligned to the pmos gates could be implanted while the second mask 700 is present.

After the source/drain extension regions are formed, sidewall spacers 908, 910 could also be formed. Normal source/drain implants could then be used to form source/drain regions. For example, n-type source/drains (e.g., N++) 912, 914 that are self-aligned to the nmos gates structures and spacers could be formed in the nmos regions. Similarly, p-type source/drains (e.g., P++) 916, 918 that are self-aligned to the pmos gates and spacers could be formed in the pmos regions. Although not shown, backend processing, such as the formation of contacts and interconnect could also be performed.

As FIG. 10 shows, aspects of the invention are also applicable to off-axis implants. As shown, in addition to 0° implants (14), 90° implants (18), 180° implants (12), and 270° implants (16); 45° implants (1002), 135° implants (1004), 225° implants (1006) and 315° implants (1008) can also be used. Other off-axis implants having other rotational angles could also be used as well. As with previously discussed embodiments, implant dose, implant specie, implant energy, and implant angle can be independently varied between these implants to allow independent channel control of transistors.

Although the invention has been shown and described with respect to one or more implementations, equivalent alterations and modifications will occur to others skilled in the art based upon a reading and understanding of this specification and the annexed drawings. For example, although the invention has been described with regards to horizontal transistors, it is equally applicable to vertical transistors. The invention includes all such modifications and alterations and is limited only by the scope of the following claims. In addition, while a particular feature or aspect of the invention may have been disclosed with respect to only one of several implementations, such feature or aspect may be combined with one or more other features or aspects of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.” Also, the term “exemplary” is merely meant to mean an example, rather than the best. It is also to be appreciated that layers and/or elements depicted herein are illustrated with particular dimensions relative to one another (e.g., layer to layer dimensions and/or orientations) for purposes of simplicity and ease of understanding, and that actual dimensions of the elements may differ substantially from that illustrated herein. Additionally, the layers can be formed in any number of suitable ways, such as with spin-on techniques, sputtering techniques (e.g., magnetron or ion beam sputtering), (thermal) growth techniques and/or deposition techniques such as chemical vapor deposition (CVD), for example.

What is claimed is:

1. A method of forming an integrated circuit, comprising:
performing first and second angled implants of a first conductivity type into first regions of a semiconductor body so as to extend at least partially under some gate electrodes associated with the first regions, where the first angled implant is performed along a first axis and the second angled implant is performed along a second axis that is laterally rotated with respect to the first axis, which second angled implant differs from the first angled implant.

2. The method of claim 1, further comprising:
performing third and fourth angled implants of a second conductivity type into second regions of the semiconductor body so as to extend at least partially under other gate electrodes associated with the second regions, where the third angled implant is performed along the first axis and the fourth angled implant is performed along the second axis, which third angled implant differs from the fourth angled implant.

3. The method of claim 2, further comprising:
forming a first mask prior to performing the first and second angled implants, where the first mask exposes the first regions and covers the second regions and where the first and second angled implants are performed while the first mask is present.

4. The method of claim 3, further comprising:
removing the first mask and forming a second mask before performing the third and fourth angled implants, where the second mask exposes the second regions and covers the first regions and where the third and fourth angled implants are performed while the second mask is present.

5. The method of claim 1, where the first angled implant has a first dosage and the second angled implant has a second dosage that differs from the first dosage.

6. The method of claim 1, where the first regions and the first and second angled implants have a common conductivity type.

7. The method of claim 6, further comprising:
forming a first mask prior to performing the first and second angled implants, where the first mask exposes the first regions; and
while the first mask is in place, performing the first and second angled implants to form pocket regions, and further performing a normal implant of at least another species of a second conductivity type to form source/drain extension regions.

8. A method of forming an integrated circuit, comprising:
forming first gates and second gates, where the first gates are oriented in a first direction and the second gates are oriented in a second direction that is laterally rotated with respect to the first direction;
performing a first angled implant along a first axis that is laterally aligned with the first direction so as to form first implanted regions respectively extending at least partially under the second gates, the first angled implant having a first conductivity type and a first dosage; and
performing a second angled implant along a second axis that is laterally aligned with the second direction so as to form second implanted regions respectively extending at least partially under the first gates, the second angled implant having the first conductivity type and a second dosage that differs from the first dosage.

9. The method of claim 8, where the first and second angled implants are performed while a first mask is in place.

10. The method of claim 8, where the first and second angled implants result in the first implanted regions under the second gates having a different doping profile than the second implanted regions under the first gates.

11. The method of claim 8, where the first gates are associated with a speed path of a microprocessor and the second gates are associated with an SRAM memory array, where the first and second gates are formed on a common die.

12. The method of claim 11, where the first and second angled implants are tailored to provide speed path transistors with a first drive current and SRAM transistors with a second drive current that is different from the first drive current.

13. A method of forming an integrated circuit, comprising:
forming first gates over n-type and p-type active regions, where the first gates are oriented in a first direction;
forming second gates over the n-type and p-type active regions, where the second gates are oriented in a second direction that is rotated with respect to the first direction;
forming a first mask to expose the one type of the active regions and cover the other type of the active regions;
while the first mask is in place, performing a first angled implant along a first axis that is laterally aligned with the first direction so as to form first implanted regions respectively extending at least partially under the second gates associated with the one type of the active regions, the first angled implant having a first conductivity type and a first dosage; and
while the first mask is in place, performing a second angled implant along a second axis that is laterally aligned with the second direction so as to form second implanted regions respectively extending at least partially under the first gates associated with the one type of the active regions, the second angled implant having the first conductivity type and a second dosage that differs from the first dosage.

14. The method of claim 13 where the one type of the active regions corresponds to the first conductivity type.

15. The method of claim 13 further comprising
removing the first mask;
forming a second mask to expose the other type of the active regions and covering the one type of the active regions;
while the second mask is in place, performing a third angled implant along the first axis that so as to form third implanted regions respectively extending at least partially under the second gates associated with the other type of the active regions, the third angled implant having a second conductivity type and a third dosage; and
while the second mask is in place, performing a fourth angled implant along the second axis so as to form fourth implanted regions respectively extending at least partially under the first gates associated with the other type of the active regions, the fourth angled implant having the second conductivity type and a fourth dosage that differs from the third dosage.

16. The method of claim 13:
where the first angled implant, second angled implant, and one type of active region share a common conductivity type; and
where the third angled implant, fourth angled implant, and the other type of the active regions share another conductivity type that is opposite the common conductivity type.

17. A method for forming an integrated circuit, comprising:
angularly implanting at least one dopant of a first conductivity type in a first manner along a first axis to form first pocket implant regions extending at least partially under some gates; and
angularly implanting at least one dopant of the first conductivity type in a second manner that differs from the first manner along a second axis that is laterally rotated with respect to the first axis to form second pocket implant regions extending at least partially under other gates.

18. The method of claim 17, where the first manner includes implanting the at least one dopant along the first axis at a first dosage, and where the second manner includes implanting the at least one dopant along the second axis at a second dosage that differs from the first dosage.

19. The method of claim 17, where the first manner includes implanting the at least one dopant along the first axis at a first energy, and where the second manner includes the at least one dopant along the second axis at a second energy that differs from the first energy.

20. The method of claim 17, where the first manner includes implanting at least a first dopant along the first axis, and where the second manner includes implanting at least a second dopant that differs from the first dopant along the second axis.
